(19) United States
(12) Patent Application Publication
(10) Pub. No.: US 2007/0148893 A1
(43) Pub. Date: Jun. 28, 2007

(54) Method of forming a doped semiconductor portion

(76) Inventors: Andrei Josiek, Dresden (DE); Georg Erley, Dresden (DE); Juergen Faul, Radebeul (DE); Martin Popp, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/314,723

(22) Filed: Dec. 22, 2005

(51) Int. Cl. H01L 21/331; H01L 21/76

(52) U.S. Cl. 438/370; 438/425; 257/E21.345

(57) ABSTRACT

A method of forming a doped semiconductor portion includes providing a semiconductor substrate with a surface, and providing protruding portions of a covering layer on the substrate surface, where the portions are arranged in a pattern of lines or segments of lines extending in a first direction. Portions of a resist layer are provided on the substrate surface, where the portions of the resist layer are arranged in a pattern of lines or segments of lines extending in a second direction, and the second direction intersects the first direction. The portions of the resist layer have a thickness d, the thickness d being measured perpendicularly with respect to the substrate surface. A tilted ion implantation step is then performed.

### FIELD OF THE INVENTION

The invention relates to a method of forming a semiconductor portion which can be used for the processing of semiconductor devices.

### BACKGROUND

In the manufacture of semiconductor devices, such as transistors which can, for example, be used in memory cells of a Dynamic Random Access Memory (DRAM), it sometimes becomes necessary to dope selected portions of the substrate. Usually, such a localized doping can be achieved by employing a hole mask. Due to this hole mask, those portions which are to be implanted—for example, by an ion beam—are opened, whereas the remaining portions of the semiconductor substrate are masked with the mask. In addition, layers which have already been processed usually serve as implantation mask. The correct positioning of such a hole mask is difficult to achieve. In particular, it is easier to properly align a mask having a lines/spaces pattern. However, a lines/spaces pattern of a deposited masking layer puts severe restrictions on the overlay.

One example in which the correct positioning of a lines/spaces mask can be difficult to achieve is the manufacturing of a transistor including a single-sided doped portion, where the transistor forms part of a DRAM memory cell. To be more specific, in this transistor the second source/drain region which will be connected with the bit line in a later process step and which is, for example, n doped, is adjacent to a single-sided p+ doped portion so as to improve the retention time of the memory cell.

The retention time refers to the time during which an information can be recognizably stored in the memory cell. The retention time can be improved by additionally performing an implantation step so as to provide a doped portion in a region adjacent to the second source/drain region. Conventionally, this single-sided doped portion as well as the second source/drain doped portion have been provided by performing an ion implantation step, using a hole mask by which those portions of the substrate surface which are not to be doped are masked with a suitable masking layer, whereas those portions which are to be doped are exposed. The conductivity type of the dopants of the single-sided doped portion is opposite to the conductivity type of the source/drain regions.

In view of the above, it is highly desirable to have a method of forming a doped semiconductor portion, by which predetermined portions of the substrate surface are doped, whereas other portions of the substrate surface are reliably not doped.

### SUMMARY

According to the present invention, an improved method of forming a doped semiconductor portion comprises providing a semiconductor substrate with a surface, providing protruding portions of a covering layer on the substrate surface, the portions being arranged in a pattern of lines or segments of lines extending in a first direction, providing portions of a resist layer on the substrate surface, the portions of the resist layer being arranged in a pattern of lines or segments of lines extending in a second direction, the second direction intersecting the first direction, the portions of the resist layer having a thickness d, the thickness d being measured perpendicularly with respect to the substrate surface, and performing a tilted ion implantation step.

Further, an improved method of manufacturing an array of transistors comprises the steps of providing a semiconductor substrate with a surface, defining a plurality of active areas formed in the semiconductor substrate, wherein the active areas are insulated from each other by isolation trenches filled with an insulating material, providing a plurality of word lines lying above the active areas, gate electrodes forming part of each of the word lines, the gate electrodes being insulated from the active areas by a gate dielectric, the word lines extending in a first direction, defining first and a second source/drain regions in each of the active areas, providing portions of a resist layer on the substrate surface, the portions of the resist layer being arranged in a pattern of lines extending in a second direction, the second direction intersecting the first direction, wherein the portions of the resist layers are arranged so as to cover part of each of the first source/drain regions, the portions of the resist layer having a thickness d, the thickness d being measured perpendicularly with respect to the substrate surface, and performing a tilted ion implantation step so that only the second source/drain regions are exposed and implanted with ions.

The above and still further objects, features and advantages of the present invention will become apparent upon consideration of the following detailed description of specific embodiments thereof, wherein like numerals designate like components in the drawings.

### BRIEF DESCRIPTION OF THE DRAWINGS

FIG. 1A depicts a cross-sectional view of a portion of a substrate when performing a method in accordance with the present invention.

FIG. 1B depicts a plan view of a portion of the substrate surface of FIG. 1A.

FIG. 2A depicts a cross-sectional view of a portion of a semiconductor substrate formed in accordance with the present invention.

FIG. 2B depicts a plan view of a portion of the semiconductor substrate of FIG. 2A.

FIG. 3A depicts a cross-sectional view of a portion of the semiconductor substrate of FIG. 2A including gate grooves formed in accordance with the present invention.

FIG. 3B depicts a plan view of a portion of the semiconductor substrate formed in FIG. 3B.

FIG. 4 depicts a cross-sectional view of a portion of the semiconductor substrate after defining the first and second source/drain regions in accordance with the present invention.

FIG. 5 depicts a cross-sectional view of a portion of the semiconductor substrate when performing an ion implantation step in accordance with the present invention.

FIG. 6 depicts a cross-sectional view of a portion of a completed memory cell in accordance with the present invention.

### DETAILED DESCRIPTION

In the following detailed description, reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing”, etc., is used with reference to the orientation of the Figures being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

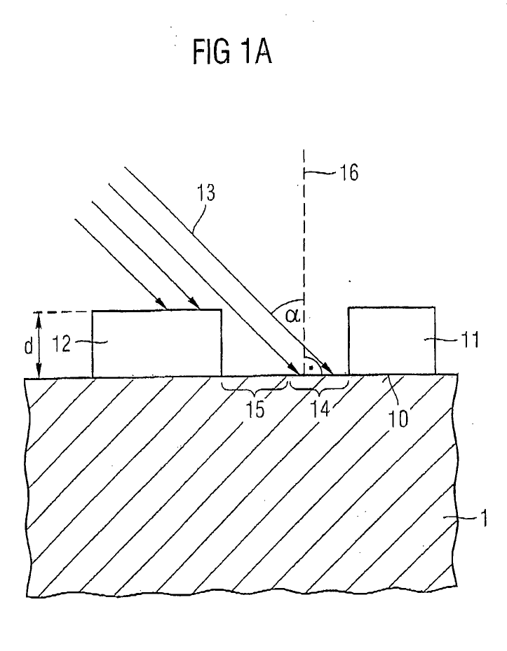

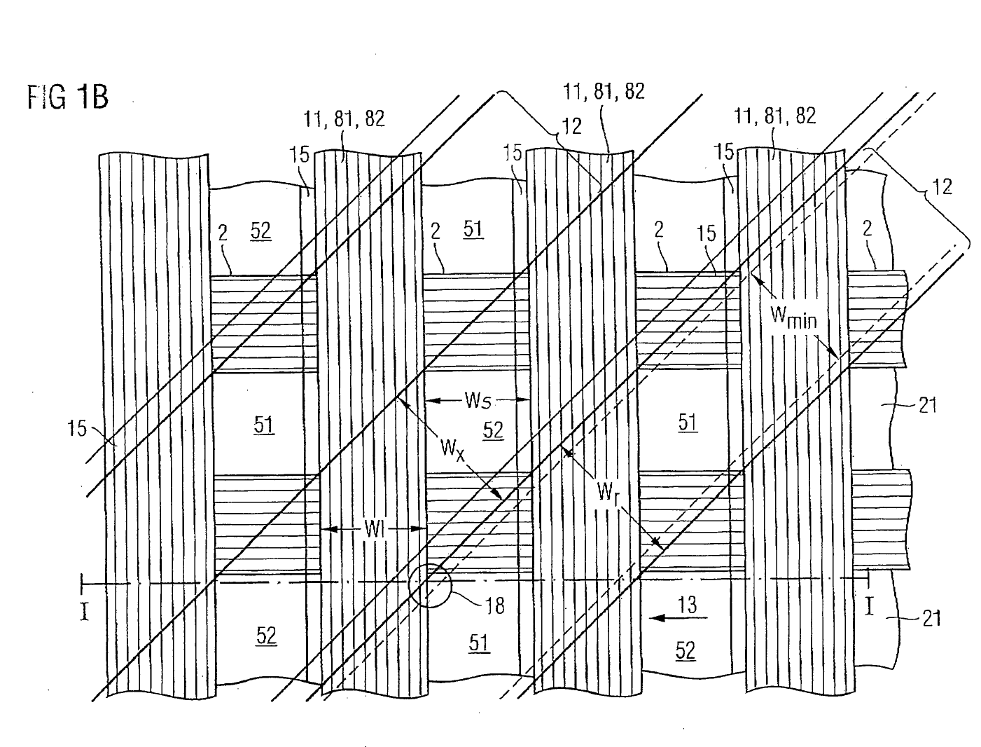

FIG. 1A shows a cross-sectional view of a semiconductor substrate 1 when performing the method of the present invention. In particular, protruding portions of a covering layer are formed on the surface 10 of the semiconductor substrate 1. The semiconductor substrate can be a silicon substrate. The covering layer may be any layer, such as a conductive layer, an isolating layer or a semiconductor layer and, in particular, may comprise a layer stack of these layers. In addition, the protruding portions of the covering layer are arranged in the pattern of lines or segments of lines extending in a first direction. Accordingly, the lines of the covering layer 11 may be word lines which are commonly used in DRAM memory cells. Nevertheless, the covering layer may be a pad nitride layer, or it may be a trench top oxide which is commonly formed on top of a capacitor trench as will be described hereinafter, or it may be part of the substrate itself. In addition, portions of a resist layer are provided on the semiconductor substrate surface 10. The portions of the resist layer 12 are arranged in a pattern of lines or segments of lines, and the lines of the resist layer extend in a second direction which is different from the first direction. Accordingly, the lines 111 are not parallel to the lines 12. As can further be seen from FIG. 1A, the resist layer 12 has a thickness d which is measured with respect to the substrate surface. The term “resist layer” refers to any layer of a material which can be patterned. In particular, the resist layer can be a photoresist layer which is patterned by exposing the layer to electromagnetic radiation and developing the exposed or unexposed portions. The resist layer may as well be any material layer which can be patterned—after applying a photoresist layer—by a photolithographic process, followed by an etching step. In particular, the resist layer may include an antireflective coating (ARC) layer or a hard mask layer as is commonly used. The cross-section of the lines or segments of lines of resist material can have a shape which deviates from the illustrated cross-section. In particular, the sidewalls need not be perpendicular with respect to the substrate surface.

When performing a tilted ion implantation step, the ion beam has an angle α with respect to the normal 16 to the substrate surface 10. Accordingly, as is shown in FIG. 1A, the ion beam 13 will be shadowed by the right hand side of the portion 12 of the resist layer. Accordingly, a portion of the exposed area between the portion of the resist layer 12 and the protruding portion 11 is implanted so as to form the doped region 14, whereas another portion of the exposed area is shadowed, thus forming the shadowed portion 15. As can be seen, the thickness d of the resist layer 12 is approximately equal to the thickness of the protruding portion 11. Typically, the thickness of the resist layer is about 50 to 300 nm. As can further be seen from FIG. 1A, the tilt angle α of the ion implantation step and the thickness d of the portion 12 of the resist layer determine the width of the doped portion 14 and the shadowed portion 15.

In particular, the angle α with respect to a normal of the surface can be in a range of 2 to 200, more preferably, of 5 to 15°. In addition, the protruding portions of the covering layer can be arranged in the form of a lines/spaces pattern. The lines can have a line width Wl, the spaces can have spaces width Ws, wherein the line width Wl is larger than the spaces width Ws.

According to a preferred embodiment, the lines correspond to word lines forming part of transistors to be formed.

Moreover, it is preferred that the portions of the resist layer are arranged in the form of a lines/spaces pattern. In particular, the lines of the resist layer can have a resist lines width Wr and the spaces between the lines of the resist layer can have a resist spaces width Wx, the resist lines width being smaller than the resist spaces width. More specifically, the resist lines width Wr can be 0.85*Wx to 0.99*Wx. As used herein, the term “*” is defined as “multiplied by.”

Preferably, the first direction intersects the second direction at an angle β, wherein β is between 40 and 50°.

According to a preferred embodiment of the invention, the thickness d of the resist layer is 50 to 300 nm.

FIG. 1B shows a plan view on an exemplary substrate surface which may be doped by a method of the present invention. As can be seen from FIG. 1B, on the surface 10 of a semiconductor substrate, there are disposed word lines 81, 82, which are formed of a conductive material. The word lines 81, 82, are formed as continuous lines. The word lines 81, 82 have a thickness d with respect to the substrate surface. In addition, lines of a resist material 12 are disposed along a second direction, wherein the second direction intersects the first direction of the word lines 81, 82. The lines of the resist layer 12 are disposed above the word lines 81, 82. In addition, isolation trenches 2 which are filled with an insulating material are disposed so as to perpendicularly intersect the word lines 81, 82. Active areas of the semiconductor substrate material are disposed between adjacent isolation trenches 2. First and second source/drain regions 51, 52 are disposed in the active areas 21. When performing an ion implantation step so as to selectively dope the second source/drain regions while not doping the first source/drain regions 51, the correct positioning of the lines 12 of the resist material is difficult to achieve. In particular, it is necessary that the lines 12 of the resist layer completely cover the first source/drain regions 51, while leaving the second source/drain regions 52 uncovered.

According to the present invention, by performing a tilted ion implantation step the overlay requirements of the positioning of the lines of the resist material 12 can be reduced. In other words, when performing a tilted ion implantation step using an ion beam 13 which is irradiated from the right side of the drawing, a substrate portion which is adjacent to the left side of each of the resist lines 12 will be shadowed. Moreover, a substrate portion which is adjacent to the left side of each of the word lines 81, 82 will be shadowed. The substrate portions 15 which are shadowed by the word lines 81, 82 and the resist lines 12 are indicated in FIG. 1B. Accordingly, the correct positioning of the lines 12 of the resist material is less critical.

In FIG. 1B, reference numeral 18 denotes an area of interest, showing a portion of the first source/drain region 51 which is directly adjacent to the word line 81, 82. During the ion implantation step to be performed, care should be taken, that the first source/drain region 51 is not doped by this doping step. Nevertheless, when employing a resist mask 12 as indicated in FIG. 1B, the lines of the resist layer should be positioned so as to make sure that the second source/drain regions 52 will be doped. Due to the shadowing effect which occurs when an ion beam 13 is irradiated at an angle α with respect to a normal to the substrate surface, the upper left hand portion of the first source/drain region 51 will not be implanted but this portion may be significantly reduced by reduction of the width Wr of the line of the resist layer as indicated by broken lines, or is slightly shifted with respect to the position shown.

In the plan view shown in FIG. 1B, the position of each of the word lines 81, 82 is fixed and depends on the previous process steps. In contrast, the position of the lines 12 of the resist layer is dependent from the overlay of the patterning process of the resist layer.

In FIG. 1B, the word lines 81, 82 typically have a width Wl of 90 nm, whereas the spaces between adjacent word lines 81, 82 Ws is approximately 80 nm, the sum of Wl and Ws corresponding to 2×F. In addition, the lines 12 of the resist material typically have a width Wr of approximately 110 nm, whereas the spaces between adjacent lines 12 Wx is approximately 130 nm. Preferably, Wx+Wr=2*F.*\sqrt{2}, (Wx+Wr=2*F*sqrt(2)) and Wx≧Wr≧0.85*Wx. As is indicated by broken lines, the resist lines should have a minimum width Wmin.

As will be explained hereinafter, the method of the present invention can be employed in the manufacture of an array of transistors, especially for use in a DRAM memory cell, wherein a substrate portion adjacent to the second source/drain region—which is to be connected with a bit line of the memory cell array—is additionally doped with a further implantation step, whereas a substrate portion adjacent to the first source/drain region is not doped.

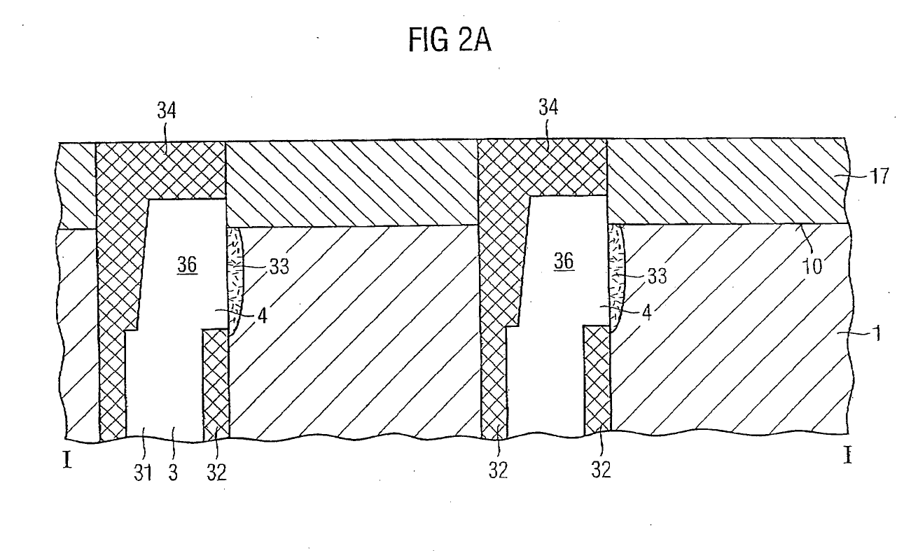

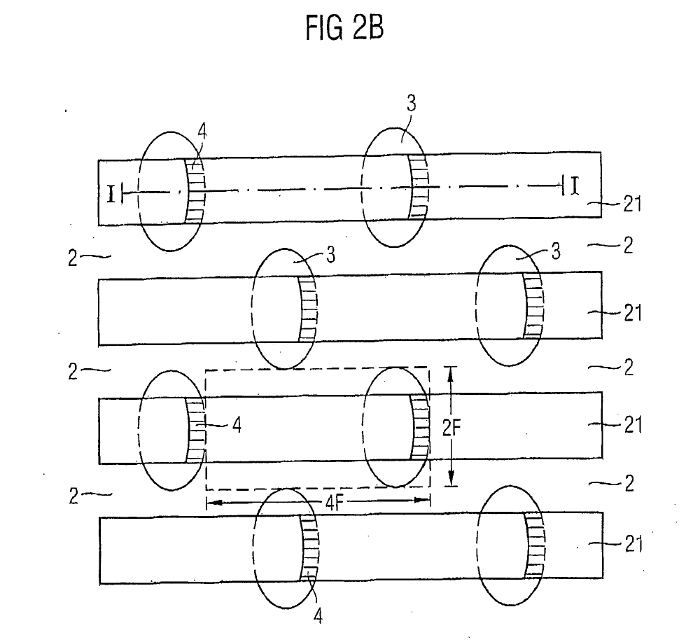

FIG. 2A shows a cross-sectional view of a semiconductor substrate 1, in which an array of trench capacitors 3 is formed. For example, the capacitor trenches 3 as shown in FIG. 2A can be formed by depositing a pad oxide layer (not shown) and a silicon nitride layer 17 as is commonly used in the art, on a semiconductor substrate 1, for example, a silicon substrate, by generally known methods.

Thereafter, the capacitor trenches are photolithographically defined by known methods. For example, openings corresponding to openings in a trench mask are etched into a hard mask layer (not shown) which is deposited above the silicon nitride layer 17. Thereafter, the openings are etched into the silicon nitride layer 17, the pad oxide layer, and the silicon substrate 1.

In addition, a first capacitor electrode and the capacitor dielectric are formed by generally known methods. Thereafter, a polysilicon filling 31 is filled into the capacitor trenches, the polysilicon filling is recessed, and an isolation collar 32 is formed in the upper portion of the trench capacitor to suppress a parasitic transistor, which could otherwise be formed at this portion. The polysilicon filling 31 forms the inner capacitor electrode. The resulting structure is filled with a second polysilicon filling and planarized by known methods. Thereafter, the polysilicon filling is recessed so that the surface of the polysilicon filling 36 lies above the substrate surface 10. Thus, a connection between the inner capacitor electrode 31 and the transistor is implemented as a single-sided surface strap or single-sided buried strap adjacent to the substrate surface 10. This asymmetric connection between the inner capacitor electrode and the transistor is provided by generally known methods.

During the following thermal steps, the dopants of the polysilicon filling 36 diffuse out passing the buried strap window to the active area 12 to form a buried strap outdiffusion 32.

As is clearly to be understood, the method of forming an array of transistors according to the present invention can be performed in combination with any type of storage capacitor, which may, of course, be different from the trench capacitor as described herein. Moreover, any type of interconnection between the storage capacitor and the transistor can be implemented.

Next, isolation trenches 2 are formed in a plane before and behind the illustrated drawing plane. Thereafter, the isolation trenches 2 are filled with a silicon dioxide material, whereby the trench top oxide portion 34 is formed. As a result, active area lines 21 are formed with two longer and two shorter sides. The active area sides 21 are delimited on either of the long sides by isolation trenches 2. The isolation trenches 2 electrically insulate neighbouring active area lines 21 from each other. Trench top oxide portions 34 are disposed on the shorter sides of the active area lines. The trench top oxide electrically insulates adjacent active area lines assigned to one row of the resultant memory cell array.

FIG. 2B shows a plan view of the resulting structure. Active areas 21 are defined by forming isolation trenches 2. Two isolation trenches are adjacent to one active area 21. In addition, the trench capacitors 3 are formed to intersect the active areas 21. The position of the cross-sectional view shown in FIG. 2A is indicated by broken lines between I and I.

Referring to FIG. 2B, the memory cells have a total area of 8F² (4F*2F), wherein F denotes the minimum lithographic feature size obtained by the technology used. For example, currently, F is 90 to 110 nm or even less. In particular, F can be any arbitrary value, such as 80, 70, 60, 50, 40 or 30 nm. As can further be seen from FIG. 2B, the capacitor trenches are arranged in a pattern so as to form a so-called checkerboard pattern. In other words, the capacitor trenches 3 of each row are staggered with respect to the capacitor trenches 3 of the neighbouring active area lines. The capacitor trenches 3 of a certain row are disposed at a half pitch between two neighbouring capacitor trenches 3 of the neighbouring rows.

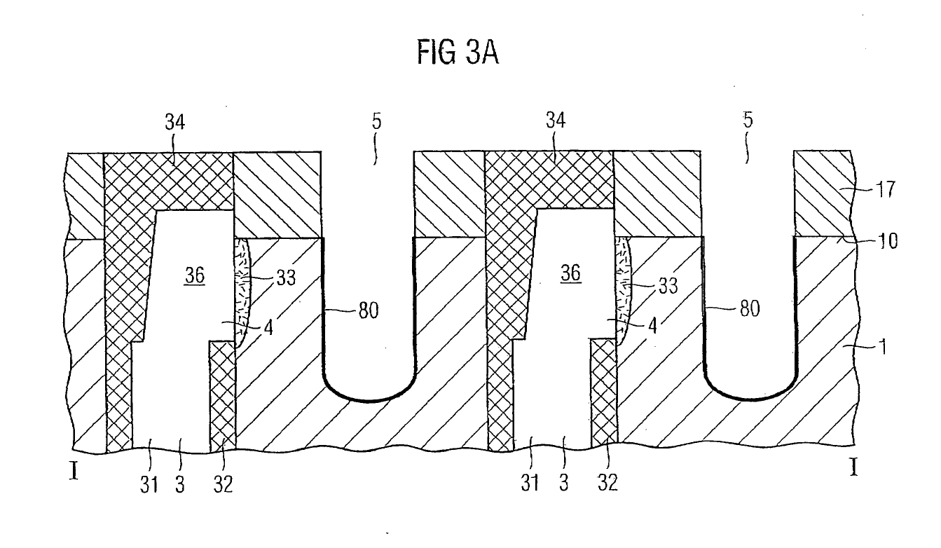

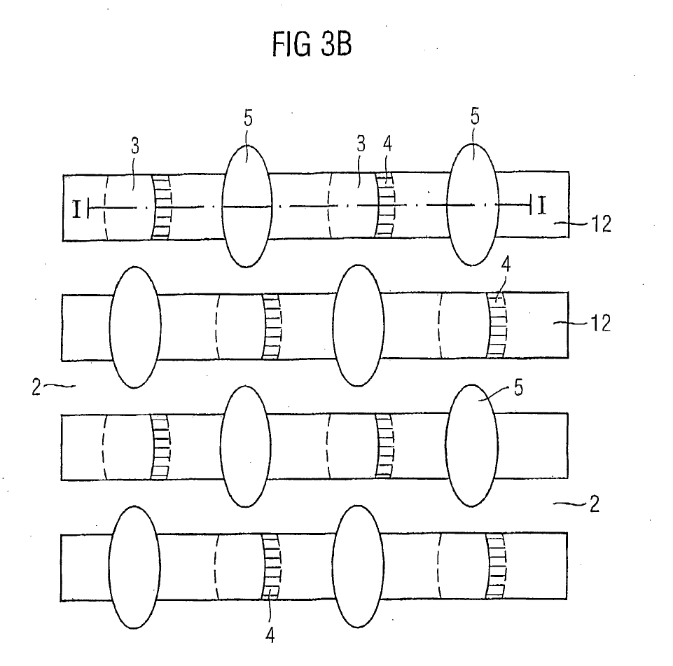

Next, gate grooves 5 are formed by etching grooves into the substrate surface in a portion of the active area using an appropriate mask for defining the grooves. For example, the grooves extend to a depth of approximately 2F from the substrate surface 10. In addition, a gate oxide 80 is thermally grown. A cross-section of the resulting structure is shown in FIG. 3A.

FIG. 3B shows a plan view on the resulting structure. The trench capacitors 3 are arranged in a checkerboard-like layout, wherein the trenches of adjacent rows are disposed at staggered positions. Between two adjacent trenches 3 of one active area line, a corresponding gate groove 5 is disposed.

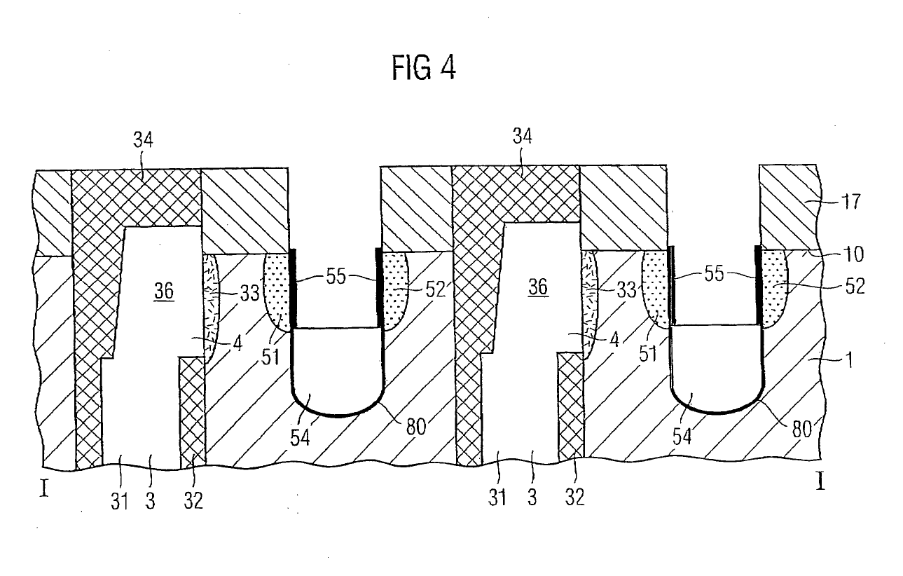

In the next step, a polysilicon layer 54 is deposited and recessed, so that the lower portion of each of the gate grooves 5 is filled with a polysilicon layer 54. In addition, a sidewall oxide is grown on the sidewalls of each of the gate grooves 5. Thereafter, an angled ion implantation step is performed so as to provide the first and second source/drain regions 51, 52. For example, the first and second source/drain regions can be n doped with As or P ions. Thereafter, an inner spacer 55, which can be made of silicon nitride, is provided. The resulting structure is shown in FIG. 4. As can be seen from FIG. 4 on the sidewalls of each of the gate grooves, silicon nitride spacers 55 are provided.

In the next step, the word lines are completed in a conventional manner. To this end, first, a polysilicon layer 56 is deposited, and a CMP (chemical mechanical polishing) step is performed so as to obtain a planarized surface. Thereafter, the pad nitride 17 and the silicon dioxide layer (not shown) are removed from the surface.

Then, a conductive layer 70 such as a tungsten layer is deposited, followed by a Si₃N₄ cap layer 87. Thereafter, a patterning step using a mask having a lines/spaces pattern is performed so as to provide the word lines 81, 82. In particular, using a photoresist mask (not shown) having a lines/spaces pattern, the layer stack including the conductive layer as well as the Si₃N₄ cap layer 87 is selectively etched so as to obtain the single word lines 81, 82.

Thereafter, a photoresist mask is generated so as to cover each of the first source/drain regions which are not to be doped in the following implantation step. To this end, a photoresist layer is deposited on the entire surface and a mask having a lines/spaces pattern is used to pattern the photoresist layer. In particular, the mask having a lines/spaces pattern is rotated by approximately 45° with respect to the direction of the word lines 81, 82. In addition, the resulting photoresist mask can have a lines/spaces pattern, wherein the width of the lines Wr is not equal to the space between adjacent lines Wx. For example, the width of the resist lines can be reduced by the approximately up to 15% with respect to the spaces between adjacent resist lines. Nevertheless, the width of the resist lines is selected so that nearly all the portions which are not to be doped are covered. Moreover, the width and the position of the resist lines as well as the tilt angle of the ion implantation step are selected so that the part of the first source/drain regions which is not covered by the resist material will be shadowed by the resist lines during the ion implantation step.

In particular, if the word lines are spaced apart by F and the resist lines are arranged at an angle of 45° with respect to the word lines, the width of the resist lines should be in a range of (F*\sqrt{2}*0.85) to (F*\sqrt{2})((F*sqrt(2)*0.85) to (F*sqrt(2)).

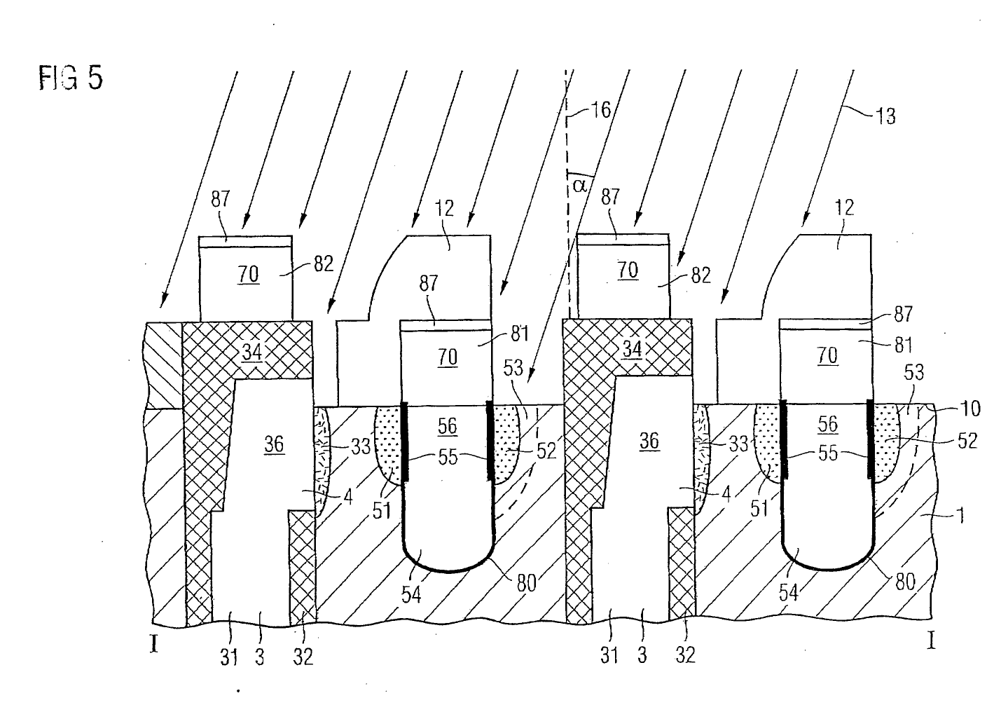

Thereafter, as is shown in FIG. 5, a tilted ion implantation step is performed so as to provide the asymmetric doped portions 53 having a dopant type which is opposite to the dopant type of the source/drain regions. For example, the asymmetric doped portion can be p doped, in particular, with B ions. At this stage, a tilted source/drain implant for the second source/drain regions may also be performed, for example with As ions.

As can be seen from FIG. 5, during this implantation step, the left hand edge of each of the resist lines 12 shadows the ion beam 13, so that only part of the spaces between adjacent word lines will be irradiated with the ion beam 13. In particular, as can be seen from FIG. 5, on the left side of each of the resist lines 12, part of the space between this resist line 12 and the adjacent passing word line 82 will not be irradiated with the ion beam. Accordingly, it is not necessary to provide the portion of the resist layer 12 so as to entirely cover the first source/drain region 51. As a consequence, a slight misalignment between the word lines and the lines 12 of the resist layer will not cause the first source/drain region 51 to be doped by this implantation step. As can further be seen from FIG. 5, in the region of the second source/drain regions 52, the whole space between the passing word line 82 and the resist line 12 is exposed so that the tilted ion beam 13 can dope the portion adjacent to the second source/drain region 52. The plan view of this process step is shown in FIG. 1B which has been described above.

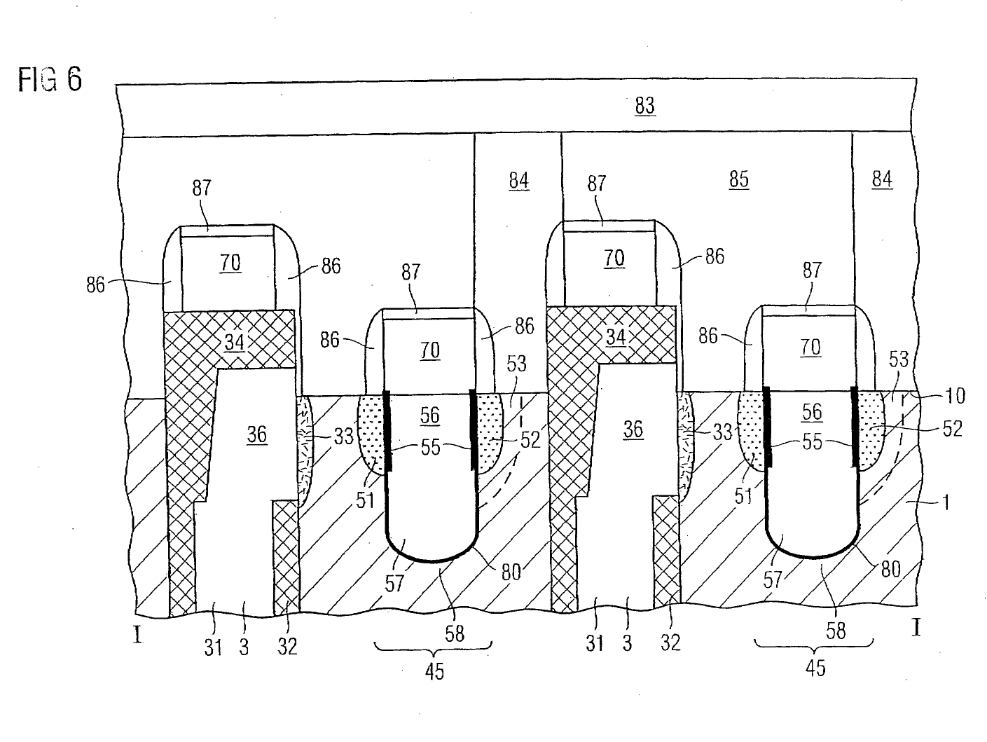

After providing the asymmetric doped portion 53, the lines of the resist layer 12 are removed and the memory cell array is completed in a conventional manner. In particular, the word lines are completed by providing the spacers 86 in a conventional manner. Further, a BPSG layer 85 is deposited. Thereafter, bit line contacts 84 are defined in a conventional manner. Then, a conductive layer is deposited so as to fill the bit line contact openings, and, optionally form the bit lines 83. Then, the bit lines are patterned so as form single lines. The completed memory cells are shown in FIG. 6.

As is shown in FIG. 6, the transistor 45 includes a first source/drain region 51 and a second source/drain region 52. A channel 58 is formed between the first and the second source/drain regions 51, 52. A gate electrode 57 is disposed adjacent to the channel. The gate electrode 57 is insulated from the channel 58 by the gate dielectric 80. The first and second source/drain regions 51, 52 are additionally insulated from the gate electrode 57 by the spacer 55. The second source/drain regions 52 are adjacent to an asymmetric doped portion 53, which, for example, can be doped with B+ ions in order to improve the retention time of the resulting memory cell and As− ions—which are doped so as to extend to a more shallow depth than the B+ ions—for the proper source/drain region. The first source/drain region 51 is adjacent to the trench capacitor 3 in which information is stored. The second source/drain region 52 is connected with a corresponding bit line 83 via a bit line contact 84. When a certain memory cell is selected by activating a corresponding word line 81, the channel 58 becomes conductive and an information stored in the trench capacitor is read out via the buried strap 33, the first source/drain region 51, the channel 58 and the second source/drain region 52 to the bit line contact 84 and the corresponding bit line 83. The gate electrode 57 is disposed in a gate groove 5 extending in the substrate surface.

As has been described above and shown in the figures, due to the special combination which is employed according to the present invention the overlay requirements can be remarkably relaxed. In particular, this combination includes a first pattern with protruding portions of a covering layer which are arranged in a pattern of lines or segments of lines and an additional pattern of portions of a resist layer, wherein the portions of the resist layer are arranged in a pattern of lines or segments of lines. The lines of the resist layer extend in a direction intersecting the direction of the lines of the covering layer, As a result, it becomes possible to perform an asymmetric doping step in a manner which assures that the portions which are to be doped will securely be doped whereas the portions which are not to be doped will securely not be doped.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

What is claimed:

1. A method of forming a doped semiconductor portion, comprising:
providing a semiconductor substrate including a surface;
providing protruding portions of a covering layer on the substrate surface, the portions being arranged in a pattern of lines or segments of lines extending in a first direction;
providing portions of a resist layer on the substrate surface, the portions of the resist layer being arranged in a pattern of lines or segments of lines extending in a second direction, the second direction intersecting the first direction, the portions of the resist layer having a thickness d, the thickness d being measured perpendicularly with respect to the substrate surface; and
performing a tilted ion implantation step, wherein the tilted ion implantation step is performed at an angle α with respect to a normal of the substrate surface.

2. The method of claim 1, wherein the angle α is in a range of 20 to 20°.

3. The method of claim 2, wherein the angle α is in a range of 5° to 15°.

4. The method of claim 1, wherein the protruding portions of the covering layer are arranged in the form of a lines/spaces pattern comprising lines with spaces between the lines.

5. The method of claim 4, wherein each of the lines has a line width WI, each of the spaces has a space width Ws, and the line width Wl is larger than the space width Ws.

6. The method of claim 4, wherein the lines correspond to word lines forming part of transistors to be formed.

7. The method of claim 1, wherein the covering layer has a thickness of 50 nm to 300 nm.

8. The method of claim 1, wherein the portions of the resist layer are arranged in the form of a lines/spaces pattern comprising lines with spaces between the lines.

9. The method of claim 8, wherein each of the lines of the resist layer has a resist line width Wr, each of the spaces between the lines of the resist layer has a resist space width Wx, and the resist line width is smaller than the resist space width.

10. The method of claim 9, wherein the resist line width Wr is in the range of (0.85*Wx) to (0.99*Wx).

11. The method of claim 1, wherein the first direction intersects the second direction at an angle β, wherein β is between 40° and 50°.

12. The method of claim 1, wherein the thickness d of the resist layer is 50 nm to 300 nm.

13. A method of manufacturing an array of transistors, comprising:
providing a semiconductor substrate including a surface;
defining a plurality of active areas formed in the semiconductor substrate, wherein the active areas are insulated from each other by isolation trenches filled with an insulating material;
providing a plurality of word lines lying above the active areas, wherein gate electrodes form part of each of the word lines, the gate electrodes are insulated from the active areas by a gate dielectric, and the word lines extend in a first direction;
defining first and second source/drain regions in each of the active areas;
providing portions of a resist layer on the substrate surface, the portions of the resist layer being arranged in a pattern of lines extending in a second direction, the second direction intersecting the first direction, wherein the portions of the resist layers are arranged so as to cover part of each of the first source/drain regions, the portions of the resist layer have a thickness d, and the thickness d is measured perpendicularly with respect to the substrate surface; and
performing a tilted ion implantation step so that only the second source/drain regions are exposed and implanted with ions, wherein the tilted ion implantation step is performed at an angle α with respect to a normal of the substrate surface.

14. The method of claim 13, wherein the angle α is selected so that an uncovered part of each first source/drain regions is shadowed by an adjacent portion of the resist layer.
